(19) United States
(12) Patent Application Publication
(10) Pub. No.: US 2026/0186543 A1
(43) Pub. Date: Jul. 2, 2026

(54) LIQUID WIRE

(71) Applicant: Microsoft Technology Licensing, LLC, Redmond, WA (US)

(72) Inventors: Christian AMOAH-KUSI, Portland, OR (US); Aleksandr Mikhailovich GERSHAFT, Redmond, WA (US); Bryan William TUTTLE, Newcastle, WA (US); David Gerard HOODMAN, Sammamish, WA (US); Nisha Susan JOHN, Bothell, WA (US); Jason Blake CHESSER, Colorado Springs, CO (US); Andrew Douglas DELANO, Woodinville, WA (US); Guixiang Ellen TAN, Portland, OR (US); Stephen Melvin RAY, Issaquah, WA (US); Naomi Yokogawa ROSELL, Issaquah, WA (US)

(21) Appl. No.: 19/005,325

(22) Filed: Dec. 30, 2024

(51) Int. Cl. G06F 1/20; H05K 7/20

(52) U.S. Cl. CPC G06F 1/206; H05K 7/20281

(57) ABSTRACT

According to one implementation, a disclosed method includes transmitting one or more commands to instruct a heat rejection unit (HRU) of the cooling system to transmit a data signal along the liquid coolant loop by controllably altering pump power between a baseline power level and a second power level that imparts a predicable change in a flow characteristic measured at a subset of the devices coupled to the coolant loop. The method further provides for sampling values of a flow characteristic at one or more of the devices both before and after altering the pump power of the first HRU and transmitting a telemetry stream including the first values to a processing system that confirms transmission of the data signal in response to detecting a pattern in the telemetry stream that matches an expected response pattern.

### BACKGROUND

Modern computing systems, including systems for providing artificial intelligence (AI) solutions, process large numbers of transactions and, therefore, consume high levels of power. As a result, such systems also generate excessive heat levels. With the increased chip power consumption and heat generation for such new AI platforms, traditional air-cooled server rack design cannot meet the cooling needs of new AI and cloud platforms. However, there are many challenges with liquid-to-air cooling technology, as this technology is not commonly used at large scale and has high power needs.

### SUMMARY

The disclosed technology provides methods for transmitting data between devices that lack direct electrical connectivity and that are coupled to a liquid coolant loop of a cooling system. The cooling system includes multiple heat rejection units (HRUs) configured to combine output flows to create an input flow received at a first information technology (IT) rack.

According to one implementation, a disclosed method includes transmitting one or more commands to instruct a first HRU of the multiple HRUs to transmit a data signal along the liquid coolant loop by controllably altering pump power between a baseline power level and a second power level that imparts a predicable change in a flow characteristic measured at a subset of the devices. The method further provides for sampling first values of a flow characteristic at a select one of the devices both before and after altering the pump power of the first HRU and transmitting a first telemetry stream including the first values to a processing system. The processing system confirms transmission of the data signal in response to detecting a first pattern in the first telemetry stream that matches a first expected response pattern defined in memory.

The above presents a simplified summary of the innovation in order to provide a basic understanding of some implementations described herein. This summary is not an extensive overview of the claimed subject matter. It is intended to neither identify key or critical elements of the claimed subject matter nor delineate the scope of the subject innovation. Its sole purpose is to present some concepts of the claimed subject matter in a simplified form as a prelude to the more detailed description that is presented later.

Other implementations are also described and recited herein.

### BRIEF DESCRIPTIONS OF THE DRAWINGS

FIG. 1 illustrates a configuration of hardware that includes a rack supporting various chassis that store computer hardware cooled by a liquid cooling system implementing the herein-disclosed technology.

FIG. 2 illustrates example sensor telemetry response patterns usable to verify that devices on the same liquid coolant loop are properly coupled to a coolant loop.

FIG. 3 illustrates a table that includes flow characteristics and corresponding power state configurations for a cooling system configuration, with characteristics that match those described in FIG. 1-2.

FIG. 4 illustrates example sensor telemetry response patterns usable to verify that an IT rack is properly coupled to a corresponding coolant loop.

FIG. 5 illustrates example operations for transmitting data between devices that lack direct electrical connectivity and that are coupled to a liquid coolant loop of a cooling system.

FIG. 6 illustrates example operations for determining whether a physical mapping of devices in a cooling system matches a stored mapping of the devices.

FIG. 7 illustrates an example schematic of a processing device suitable for implementing aspects of the disclosed technology.

### DETAILED DESCRIPTION

Although liquid cooling technology is in high demand to support the high cooling needs of AI platforms, data centers have been traditionally air-cooled, and few data centers have liquid cooling reservoirs. To address growing demands, liquid-to-air heat rejection units (HRUs) are being integrated into many modern cooling systems. A liquid-to-air HRU is a type of heat exchanger system that typically includes one or more fans that pull cold air in from the air conditioning system of the surrounding room where it comes into contact with a series of coils, tubes, or plates that contain a liquid coolant flow and that conductively draw heat away from liquid coolant and exchange the heat with the passing air, warming an airstream that is provided back to an intake of the room's air conditioning system.

It is common for an HRU to include multiple coolant channels that help to dissipate heat and that include pumps that direct the liquid coolant through the channels. Each HRU further includes a control system that independently manages pump and fan speed. The temperature of the coolant leaving the HRU is a function of pump speed, fan speed, and air temperature at an inlet of the liquid-to-air HRU. An operator typically selects a fixed temperature setpoint and a control mode for the pumps that causes the control system to drive the pumps to ensure either a fixed flow rate or a fixed pressure. The control system operates the pumps to meet the flow rate or pressure setpoint and drives the fan(s) of the HRU to ensure that the coolant leaving the HRU is at a target temperature.

To achieve higher cooling efficiency, some cooling systems are beginning to adopt designs that link together multiple HRUs. For example, multiple HRUs are arranged to deliver parallel current flows to one or multiple information technology (IT) racks that house heat-generating chips that require cooling. In an example parallel HRU design, “hot” coolant leaving an IT rack is split into channels directed through separate HRUs. The HRUs cool the channels in parallel and more efficiently than a single HRU due to increased surface area and flow throughput. The HRUs then output cooled flows that are recombined and, subsequently, re-circulated through the IT rack or through multiple IT racks fed in parallel by the recombined liquid coolant flow.

In these new liquid-to-air cooling systems, it is advantageous to allow HRUs and IT racks to communicate with one another for various reasons. For instance, when a new group of HRUs is initially brought online in a data center and uplinked to a management system, the management system may establish incorrect logical groupings of the HRUs without the ability to verify which HRUs are physically coupled to a same coolant loop and the identities of IT racks cooled by each coolant loop. When these types of logical configuration errors occur, HRUs in different coolant loops may be commanded as if physically arranged in a same coolant group, which can potentially lead to unexpected behavior that does not cool IT racks as expected. It addition to the potential for incorrect logical configurations, it is also possible that a maintenance technician may accidentally couple hoses to the wrong ports, which can create loops that do not operate as intended, causing IT equipment to be undercooled or overcooled. Therefore, it is desirable to be able to execute a communication “handshake” of sorts between the HRUs and IT racks on the same coolant loop to affirm that the physical couplings match the expected mapping of logical device identifiers. Likewise, there exist scenarios where it would be useful for a failure in one HRU (e.g., a failure of pump(s) or fan(s)) to communicate with other HRUs operating on the same coolant loop. If, for example, one HRU is experiencing a critical multi-pump failure, it could be advantageous for the HRU to be able to quickly signal the IT rack on the same loop with an instruction to power down before the IT rack senses the temperature increase and experiences damage as a result.

However, a major design challenge in these multi-HRU cooling system loops pertains to facilitating communications between HRUs and IT racks on each cooling loop. With the already-existing complex electrical cabling connecting different trays in an IT rack and different racks to one another, there is limited space in a data center to provide new wired connections in these new liquid cooling systems that support connections between HRUs (e.g., that are coupled to a same coolant loop) or between HRUs and IT racks.

The herein-disclosed technology includes a mechanism that allows electrical devices on the same coolant loop (e.g., HRUs and IT racks) to transmit signals along the liquid flow in the coolant loop, decipher telemetry transmitted along the liquid flow, and use this telemetry to determine the states of other devices coupled to the same coolant loop. For example, this technology allows the devices on the same coolant loop to perform operations that make it possible to confirm agreement between actual (operator-assembled) physical configurations and expected (stored) logical configurations. Additionally, this technology potentially lends itself to applications of diverse scope, such as to allow HRUs to instruct IT racks to communicate critical failures and, consequently, take timely protective actions to safe equipment.

According to one implementation, the foregoing is realized by using circulating liquid coolant as the medium that communicates a data signal, essentially using the coolant medium as a “liquid wire.” Each HRU and IT rack is equipped with at least one pressure gauge, flow rate sensor, and temperature sensor to receive signals transmitted via the liquid wire that are subsequently compared to response patterns stored in memory to interpret the underlying signals.

In one implementation, a HRU on a liquid coolant loop acts as a transmitter by controllably altering its internal pump power to impart a predictable change in a flow characteristic measured at other device(s) on the same coolant loop. Another device, such as an IT rack or other HRU on the same coolant loop, receives the transmitted signal by sampling flow characteristics, such as pressure and flow rate, that contain the signal. To detect the signal, the sampled telemetry is analyzed and compared to one or more stored telemetry response patterns. This detection may, in various implementations, be performed by the device that acts as the receiver or by an external processing system. For example, an IT rack may receive a signal transmitted by a HRU and transmit sensor telemetry to an external processing system, such as a rack controller, that extracts the signal from the sensor telemetry.

The herein-disclosed use of coolant as the medium for data signals eliminates the need for electrical couplings between HRUs and IT racks on the same coolant loop, which significantly reduces the complexity of installing and maintaining liquid cooling systems that utilize liquid-to-air cooling technology.

Although certain aspects of the disclosed technology are suggestive of techniques utilized in rudimentary fluid systems (e.g., measuring responses to changes in pressure and flowrate), a major hurdle of implementing the disclosed technology relates to the transmission of data using a coolant loop within a “live” cooling system—meaning, a cooling system that is actively being used to cool an IT rack while the IT rack is powered on and performing heat-generating computations. In such a system, even small disturbances in the coolant flow have the potential to alter the temperature of coolant being delivered to electronics that have tight margins for thermal tolerance. Techniques disclosed herein address this unique challenge and thereby ensure thermal stability at times when the coolant loop is being used to transmit data.

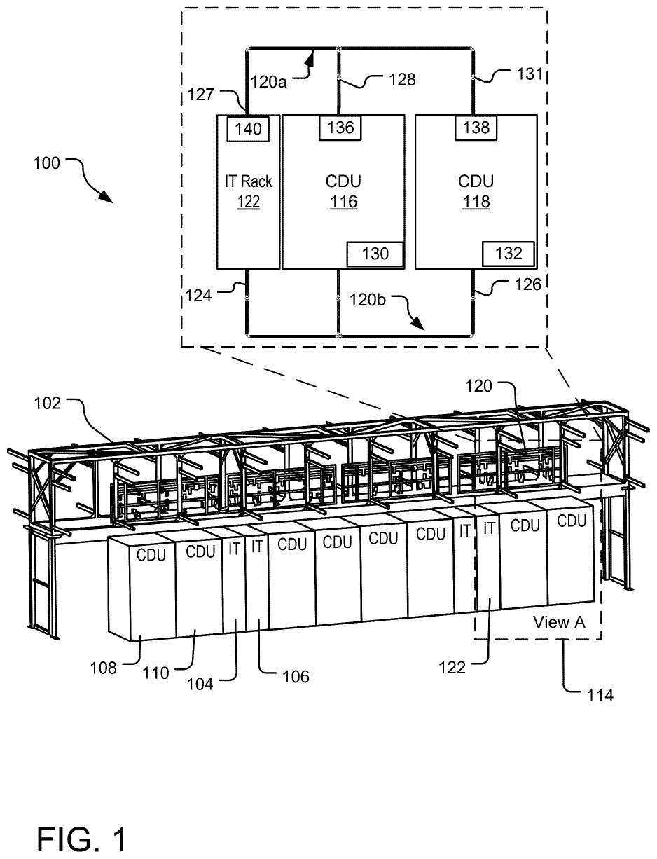

FIG. 1 illustrates a system 100 that includes a rack supporting various chassis, referred to herein as information technology (IT) racks, that store computer hardware cooled by a liquid cooling system implementing the herein-disclosed technology. Each IT rack (e.g., IT racks 104, 106, 122) includes an outer housing that contains processing equipment and other computer hardware, such as graphics processing units (GPUs) and hardware accelerators used to support AI applications. The cooling system includes multiple heat rejection units (HRUs 108, 110) and manifolds (e.g., a manifold 120) that couple various HRUs to different IT racks. Although the disclosed technology may be implemented in systems that support any number of HRUs and IT tracks in each coolant loop, the implementation shown in FIG. 1 is a 2-to-1 configuration in which each IT rack is cooled by a pair of HRUs. The rack 102 of FIG. 1 supports four different closed coolant loops, each of which includes two HRUs, a manifold, and a single IT rack.

For example, a first coolant loop 114 includes a first HRU 116, a second HRU 118, the manifold 120, and an IT rack 122. In View A, all components of the manifold 120 are shown to be positioned on top of HRUs 116 and 118 and the IT rack 122. However, for clarity, View B includes a system diagram of the first coolant loop 114 with manifold components shown more clearly. Specifically, the manifold 120 includes a hot side 120a and a cold side 120b. Warm coolant leaving the IT rack 122 flows through the hot side 120a, where it is split into parallel channels 124 and 126, each of which passes through a different one of the first HRU 116 and the second HRU 118. Within each of the first HRU 116 and the second HRU 1118, the coolant may be split into additional parallel channels that include pumps to circulate the coolant through one or more liquid-to-air heat rejection units (HRUs) (not shown) that pull heat away from the coolant and transfer the heat to air circulated by fans (not shown). The coolant then exits the first HRU 116 and the second HRU 118 on the cold side 120b of the manifold, where parallel channels from the first HRU 116 and second HRU 118 are combined to create a single input flow to that enters the IT rack 122 at a coolant inlet 127.

Each of the HRUs (116, 118) includes a chassis that houses a sensor package 134 or 136 including a pressure gauge, flow rate sensor, and temperature sensor in-line with the coolant flow. In addition, each of the HRUs (116, 118) includes an on-board control system, shown in FIG. 1 as control systems 130 and 132, respectively. The control systems 130 and 132 include memory that stores firmware, a processor for executing firmware, and communication system including a transmitter and receiver that communicates with a rack-level controller (not shown) that provides monitoring of flow characteristics for system safety and high-level control management, such as to provide power to the HRUs and IT racks arranged on the rack 102.

The IT rack 122 includes a sensor package 140 that provides functionality similar to that described above with respect to the sensor packages 136 and 138. In one implementation, the sensor package 140 is located proximal to the coolant inlet 127 and includes a pressure gauge, flow rate sensor, and temperature sensor. In some implementations, the sensor package 140 is attached to or integrated within a chassis of the IT rack 122. In other implementations, the sensor package is integrated within a smart hose of the manifold 120 that couples with the coolant inlet 127. In some implementations, the sensor package 140 includes a transmitter that transmits sensor measurements to an external processing system, such as a rack-level controller.

In one implementation, the first coolant loop 114 is selectively operated at setpoints designed to ensure that the first HRU 116 and the second HRU 118 provide equivalent contributions to the input flow that is received at the IT rack 122 when functioning nominally—meaning, with the IT rack powered on and all fans and pumps fully functioning. In this scenario, the first HRU 116 contributes 50% of the flow received at the coolant inlet 127, and the second HRU 118 contributes the other 50% of the flow. In the system 100, it is assumed that either the first HRU 116 or the second HRU 118 has the capability to supply the full target flow to the coolant inlet 127 of the IT rack 122 in the event that the other fails. Thus, under nominal operating conditions, the pumps within the first HRU 116 and the second HRU 118 may be run at a power level that is 50% of the maximum power that either HRU can independently provide.

Although different implementations may have different features, the manifold 120 includes check valves 128 and 131, which are designed to automatically close when the coolant loop is pressurized to prevent backflow from the cold side 120b of the manifold to the HRUs 116, 118. Although the check valves 128 and 131 are closed when the cooling system is fully pressurized and operating nominally, the check valves 128 and 131 may, in actual implementations, close under slightly different operating conditions and at slightly different points in time—both within a single cooling loop and across different coolant loops supported by the rack 102. These slight differences in the timing of valve closures make it difficult to predict values of flow characteristics at lower pressures.

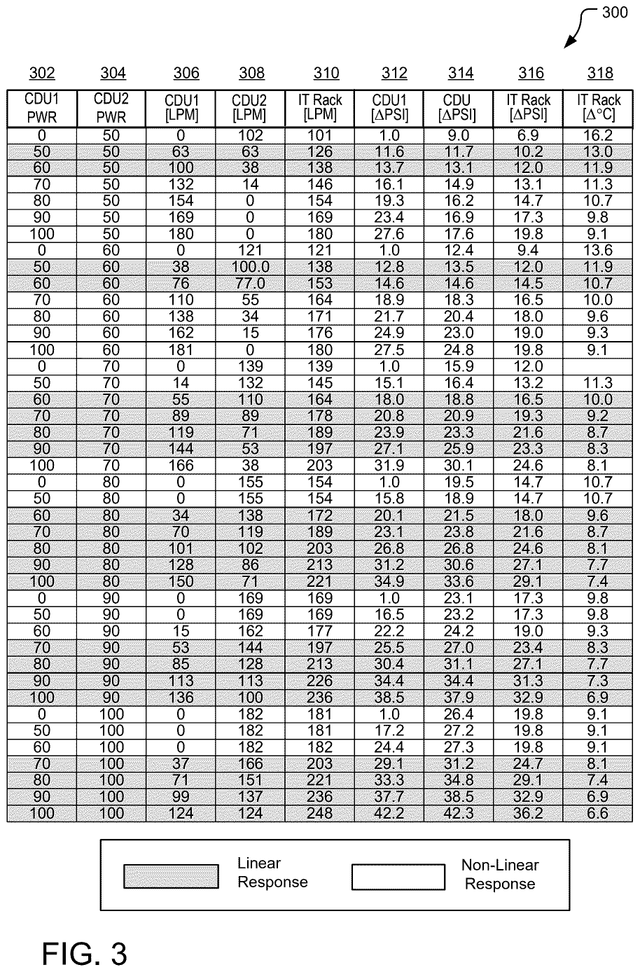

Under certain operating conditions, a linear response function exists that is usable to predict the flow characteristics of the coolant flowing throughout the first coolant loop 114. What this means is that if the pump power of the first HRU 116 or the second HRU 118 is altered without changing other system conditions, the linear response function can—if appliable—be used to predict a corresponding observed change in pressure, flowrate, and temperature at each different sensor packages 140, 136, and 138 within the first coolant loop 114. Notably, the unpredictability in the timing of closure for the check valves 128 and 131 renders the linear response function inapplicable at lower ranges of pump power correlating with lower system pressures. Likewise, experimental tests have surprisingly shown that the linear response function is also inapplicable when the first HRU 116 and the second HRU 118 are operating respective pumps at different power levels and when the magnitude of this difference exceeds a threshold. Exemplary data illustrating applicability of the linear response function is shown and discussed with respect to FIG. 3.

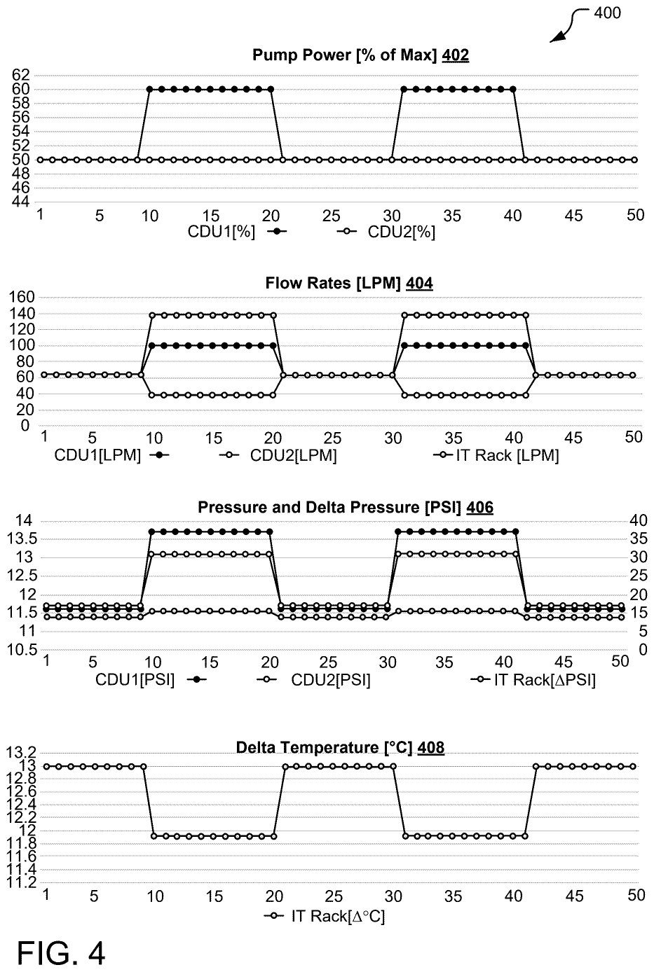

In one implementation, the first HRU 116 and the second HRU 118 are commanded to controllably vary pump power to encode a data signal within the liquid coolant that is circulating through the first coolant loop 114. When this is done under precisely selected operating conditions, the linear response function can be leveraged as a way of detecting the encoded signal. In examples of this discussed in further detail with respect to FIG. 4, the first HRU 116 transmits a signal by varying its internal power level in a precise way. These changes in the pump power of the first HRU 116 predictably alter the flow characteristics (e.g., flow rate and pressure) throughout the coolant loop, including those detected by the sensor package 138 in the second HRU 118 and the sensor package 140 in the IT rack 122. Sensor measurements taken within the second HRU 118 and the IT rack 122 are then transmitted to the rack-level controller (or other external processing system) where they are compared to expected values, referred to herein as an “expected response pattern,” that is stored in memory. This expected response pattern is a pattern of measurements that is given by the applicable linear response function based on the system power configuration (e.g., pump power levels for HRU 1 and HRU2) at any given point in time.

In one implementation, the first HRU 116 executes a sequence of commands that cause it to vary its pump power one or more times and thereby transmit a signal that can be observed in the pressure and/or flow rate measurements sampled at other device(s) within the same coolant loop. Upon receiving these sensor measurements at the rack controller (or other external processing system) and confirming the observed sensor values match the expected response pattern associated with the firmware sequence, the rack controller can then independently confirm which device(s) are coupled to the first HRU 116. This provides a way to confirm that the actual physical configuration of the devices matches the configuration stored for the corresponding logical device identifiers.

Although the examples provided herein are limited to signals usable to confirm physical mappings between devices on a coolant loop that lack direct electrical connectivity, the disclosed technology can, in other implementations, be leveraged to transmit other information directly between devices coupled to the same coolant loop. For example, the first HRU 116 might transmit a “critical error” signal by modulating its pump power in a particular way, such as by driving pump power high and then low at precisely selected timing intervals, like Morse code. In this implementation, the IT rack 122 executes logic that monitors the pressure and flow rate sampled at the sensor package 140 and compares sampled sensor values to a predefined and stored response pattern for the “critical error” signal. When the “critical error” signal is observed in the fluctuating pressure and/or flow rate values of the coolant flow, the IT rack 122 take preemptive action in a timely manner—e.g., well before detecting an impending rise in temperature with the potential to harm electronics.

In one implementation, the IT rack 122 responds to receipt of the above-described critical error signal by transitioning into a power throttling mode to reduce power usage, such as by shutting down some, but not all, servers on the rack to support some ongoing computational operations while the system has reduced cooling capability. In yet another implementations, the IT rack 122 responds to the above-described critical error signal received via the liquid coolant loop by instructing its respective servers to perform more frequent saves during computational operations (e.g., by more frequently copying data in volatile memory to non-volatile memory), which provides increased data protection at times when the chance of complete cooling failure is known to be high. These scenarios are merely exemplary of the many ways it could be advantageous to transmit telemetry via the liquid coolant.

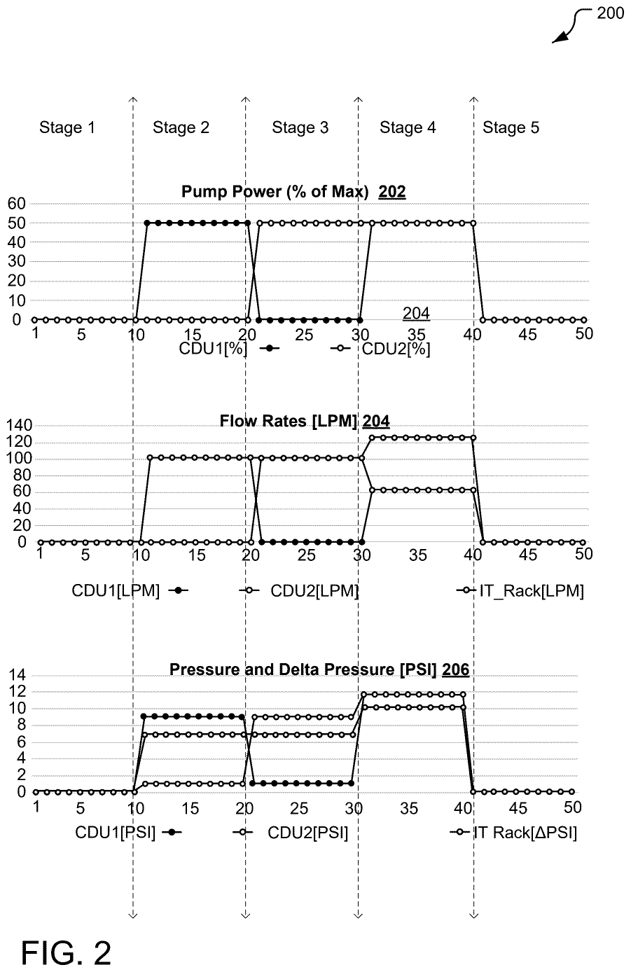

FIG. 2 illustrates example sensor telemetry response patterns 200 that, when observed within a cooling system implementing the disclosed technology, are usable to verify that devices on the same liquid coolant loop are free of leaks and physically configured in a way that matches a stored logical mapping of corresponding device identifiers. The data shown in FIG. 2 is presumed to be collected from devices in a coolant loop with physical characteristics similar to that described with respect to the first coolant loop 114 of FIG. 1—namely, a coolant loop with two HRUs that provide parallel flow combined to generate a flow that is input to an IT rack. The HRUs and IT rack include sensor packages that enable each device to measure flow characteristics device (e.g., flow rate, pressure, and temperatures) of coolant that is flowing through the device. Additionally, the sensor packages are equipped with memory and a processor. The memory stores a firmware sequence that causes the sensor packages to sample the flow characteristics at regular intervals (e.g., once per second or every few seconds) and transmit the sampled values to an external processing system, which is to be understood as a processing device that is external to the cooling loop including the devices that it is communicating with (meaning, the external processing system is not cooled by the coolant loop).

FIG. 2 includes plots 202, 204, and 206, which collectively illustrate power configurations and corresponding flow characteristics sampled by sensors proximal to various devices coupled to the coolant loop. These devices include two HRUs, referenced as HRU1 and HRU2, and an IT rack. Cooled flows output by HRU1 and HRU2 are recombined into a single input flow received at the IT rack, as generally described with respect to FIG. 1.

In the example shown, the external processing system (e.g., rack controller) transmits individual commands to HRU1 and HRU2 that instruct the HRUs to vary their respective pump power between a baseline power level (e.g., zero in this example) and a comparatively higher pump power (e.g., 50% in this example) at staggered times. Throughout the time period corresponding to the sensor telemetry response patterns 200 (e.g., t=0 through t=50), the IT rack is powered off or in a state that does not require cooling. At this point in time, the IT rack is not being used to perform AI computations. For example, the data shown is collected at a time when the coolant loop is turned on for the first time following the assembly of the cooling system and its respective physical couplings by a data center technician.

To confirm that HRU 1 and HRU 2 are coupled to the same IT rack and to the IT rack with the logical identifier that is stored in the expected mapping, the external processing system executes a five-stage sequence referred to herein as a “Coolant Loop Initiation Sequence.” It is assumed that at the time this sequence is executed, an external processing system is programmed with a mapping of logical device identifiers for devices in the system 100 and a mapping of expected physical couplings between those devices; however, it is not yet known with any certainty whether the data center technician has coupled the HRU1 and HRU to the IT rack having the logical identifier that is associated, in a stored mapping, with the logical identifiers for HRU1 and HRU2.

During the Coolant Loop Initiation Sequence, the external processing system commands the HRUs to controllably vary pump behavior in a particular way with the objective of testing which device(s) those HRUs are coupled to via the coolant loop. Throughout the Coolant Loop Initiation Sequence, the sensor packages of HRU1, HRU2, and the IT rack sample flow characteristics at regular intervals, such as every few seconds, and transmit the sampled values to the external processing system. In scenarios where the actual physical coupling between devices matches what is logically expected (e.g., per a mapping of logical device identifiers stored by the external processing system), the above-described controllable variance in HRU pump power imparts predictable changes on the sampled flow characteristics.

The five-stage Coolant Loop Initiation Sequence is generally shown in FIG. 1 by annotations “Stage 1”, “Stage 2”, “Stage 3”, “Stage 4”, and “Stage 5.” The plot 202 illustrates variations in HRU pump power throughout the 5-stage sequence. The plot 204 illustrates flow rate values sampled at HRU1, HRU2, and the IT rack throughout the Coolant Loop Initiation Sequence. The plot 206 illustrates pressure values sampled at HRU1, HRU2, and the IT rack throughout the Coolant Loop Initiation Sequence.

During a first stage of the Coolant Loop Initiation Sequence (e.g., t=0 through t=10) both HRUs are maintained with pumps operating at the baseline power level. In this example, the baseline power level is zero, and the pumps remain off throughout stage 1. The purpose of stage 1 is to collect baseline pressure values at the various devices, as is generally shown the plot 206. The data collected pertains to a system with check valves designed to automatically close to prevent backflow into HRU1 and HRU2 when the system is pressurized, similar to that shown and described in FIG. 1. In different HRUs, these check valves may close at slightly different points in times as pressure increases in the system after the pumps are turned on. Sampling baseline pressure at the time that these valves are open (in Stage 1 when HRUs are off) makes it possible to determine a magnitude of pressure increase that occurs when HRU pump power is controllably ramped to the higher power level.

Upon commencement of stage 2 (t=11 through 2=20), the external processing system commands HRU1 to increase its pump power from the baseline level (zero) to the higher power level. In the example shown, the “higher power level” is 50% of the maximum pump power that HRU1 is capable of. In different implementations, the selection of the setpoint for this higher pump level is influenced by two factors-namely, leak potential and the need to obtain strong signals for the sampled flow rate and pressure values. If the cooling system is being turned on for the first time, the potential for a leak due to a loose or faulty coupling is higher than if the cooling system has been running for a while. To mitigate damage caused by a potential leak, it is therefore desirable to conduct the Coolant Loop Initiation Sequence at pump power levels that are as low as possible (e.g., by toggling HRU power between zero and a non-zero pump power that is still quite low in case there is a leak in the line). At the same time, it is desirable to increase the pressure enough to cause the check valve to close at the input to HRU2. When this occurs, a slight pressure increase is observable in HRU2 (during stage 2), which signals the successful operation of the check valve. In other implementations, the “higher power level” assumed by HRU1 during stage 2 may be higher

When HRU1 is operated at the higher pump level (50% of max) and HRU2 is at the baseline power level (off) in Stage 2, it is expected that the flow rate through the IT rack will match the flow rate out of HRU1, with no flow detected at HRU2. In reviewing the sensor telemetry response patterns 200 corresponding to Stage 2, the external processing system confirms that the flow rate values sampled by HRU1 toggle between zero flow rate (at the end of Stage 1) to a higher flow rate (during Stage 2) and further confirms that the higher flow rate matches a flow rate sampled at the first HRU while the HRU is operating at the higher power level. Successful detection of this flow rate pattern therefore allows the external processing system to verify that HRU1 is coupled to the IT rack, as expected. For example, the sensor data received from the IT rack is packaged with a logical device identifier for the IT rack, and the external processing system can confirm, from the sensor telemetry response patterns 200 for Stage 2 that HRU 1 is coupled to the device with this logical device identifier. If the sensor telemetry response patterns 200 observed during Stage 2 do not match the above-described expected response patterns, the external processing system generates a notification that flags a potential physical configuration error between the HRU1 and the IT rack.

During Stage 3 of the Coolant Loop Initiation Sequence (t=21-30), the external processing system commands HRU1 to turn its pumps off (transitioning back to the baseline power level) and commands HRU2 to turn its pumps on to the higher power level (e.g., 50% of the max). Stage 3 is, therefore the reverse of Stage 2, and it is expected that during this stage, the flow rate through the IT rack will match the flow rate out of HRU2 with no flow detected at HRU1. The detection of the flow rate pattern shown in the plot 204 during Stage 3 therefore allows the external processing system to verify that HRU2 is correctly coupled to IT rack, with no leaks. If the sensor telemetry response patterns 200 observed during Stage 3 do not match the above-described expected response patterns, the external processing system generates a notification that flags a potential physical configuration error between the HRU2 and the IT rack.

During Stage 4 of the Coolant Loop Initiation Sequence (e.g., t=31 through t=40), the external processing system commands both HRU1 and HRU2 into the higher power level. The purpose of this stage is to ensure that the two HRUs operate correctly together on the same manifold without blocking one another flows. In the illustrated example, Stage 4 entails commanding both HRUs to operate at 50% of the max pump power level. It is, in this case, expected that the flow rates through HRU1 and HRU2 will match one another and that the sum of flow rates through HRU1 and HRU2 will match the flow rate measured through the IT rack. It is further expected that both HRUs will observe a pressure that represents an equal magnitude increase as compared to the corresponding measured baseline pressure of that HRU (e.g., during stage 1). If either HRU malfunctions in this stage, such as by not driving its pumps to the target power level, it is likely to observe flow rates or pressure changes at HRU1 and HRU2 that do not match this expected response pattern.

Interestingly, it is not trivial to test the functionality of multiple HRUs in a concurrent operative state because the measured flow characteristics (pressure and flow rate) do not follow a predictable linear response pattern at all possible combinations of pump power levels for the HRUs. For example, operating HRU1 at 30% power and HRU2 at 60% power would not necessarily result in a 30/60 split in the corresponding flow rates measured at HRU1 and HRU2. Instead, experimental data has shown that flow characteristics are predictable exclusively for certain power configurations of the system (e.g., select pairs of power levels for HRU1 and HRU2). Implementing the disclosed technology may therefore entail experimentally identifying a selection of power state configurations that impart predictable responses in flow characteristics (pressure and flow rate) measured at different devices coupled to the same coolant loop within the cooling system configuration of interest. Example data for identifying this selection of power state configurations is shown in FIG. 3.

For the 2-to-1 HRU-to-IT Rack configuration corresponding to the illustrated dataset, the power configuration of Stage 4, where the HRUs are operated at identical power levels, is one configuration that allows flow characteristics to be predicted via the linear response function.

If the sensor telemetry response patterns 200 observed during Stage 4 do not match the above-described expected response patterns, the external processing system generates a notification that flags a potential malfunction of HRU1 or HRU2 or that suggests re-checking the connections between HRU1 and HRU2.

During Stage 5 of the Coolant Loop Initiation Sequence (e.g., t=41 through t=50) the HRUs are commanded to again enter the baseline power level (e.g., zero power). Provided the sensor telemetry response patterns 200 match the expected response patterns that are described above and stored in memory accessible by the external processing system, the external processing system records data (e.g., in a logfile or otherwise) indicating successful completion of the Coolant Loop Initiation Sequence.

FIG. 3 illustrates a table 300, which includes flow characteristics and corresponding power state configurations for a cooling system configuration with characteristics matching those described with respect to FIG. 1-2, above. The cooling system has two HRUs that operate in parallel to cool a flow that is supplied to an IT rack, consistent with the physical configuration described with respect to FIGS. 1 and 2. As noted above, experimental data has shown that flow characteristics do not behave linearly in response to linear increases in the pump power of a single HRU. The table 300 illustrates controlled changes in pump pressure for HRU 1 and HRU2 (see pump pressure in columns 302 and 304) and corresponding observed changes in flow rate, pressure, and temperature. Specifically, columns 306, 308, and 310 illustrate observed changes in flow rate at HRU1, HRU2, and the IT rack, respectively, while columns 312, 314, and 316 illustrate observed changes in pressure at HRU1, HRU2, and the IT rack, respectively, while column 318 illustrates changes in temperature at the IT rack.

Data in the table 300 confirms that a linear response function can be used to predict the corresponding flow characteristics (pressure, flowrate, and temperature) exclusively for power configurations in which HRU1 and HRU1 operate within 20% of the same power level (on a scale where each HRU can be operated from 0 to 100% power level). Rows identifying power configurations that generate linear (predictable) values of the flow characteristics are shaded, while power configurations corresponding to non-linear (non-predictable) values of the flow characteristics are unshaded. Signals transmitted through the coolant medium may therefore be constructed by transitioning the cooling system between two or more power configurations selected from the shaded subset of power configurations that yield predictable flow characteristics.

FIG. 4 illustrates example sensor telemetry response patterns 400 that, when observed within a cooling system implementing the disclosed technology, are usable to verify that an IT rack has been correctly coupled to a corresponding coolant loop such that no fluid is escaping the system, and the IT rack is physically coupled to the correct ports/hoses of the cooling system. Unlike the telemetry response patterns described with respect to FIG. 2, the sensor telemetry response patterns 400 are observed in response to a test operation sequence that is referred to below as the “IT Rack Replacement Test Sequence.”

Like the other examples provided herein, the sensor telemetry response patterns 400 are observed within a cooling system that includes a pair of HRUs (referred to below as HRU1 and HRU2) that provide parallel cooling to prepare an input stream for one or multiple IT racks. A sensor package is included within HRU1, HRU2, and the IT rack(s). These sensor packages are programmed to transmit sensor measurements to an external processing system at regular intervals, such as every 1 second or every 3 seconds.

In some implementations, the IT Rack Replacement Test sequence is executed while at least one IT rack on the coolant loop is powered on and being cooled by the loop. For example, the coolant loop may include multiple IT racks cooled by a pair of HRUs. When a first IT rack is being replaced or repaired, other IT rack(s) continue operating nominally while being cooled by the coolant loop. When the first IT rack is re-coupled to the coolant loop, the IT Rack Replacement Test Sequence is performed to ensure the newly-replaced IT rack is correctly coupled (without leaks or malfunction) to the correct locations on the coolant loop such that the coolant flows between devices as expected in a stored mapping of logical identifiers. Notably, the IT Rack Replacement Test Sequence can be performed without stopping the flow of coolant in the coolant loop and without powering down the other IT rack(s) being cooled by the same loop.

During the IT Rack Replacement Test Sequence, pump power is modulated between a high value and a low value in a single HRU while keeping pump power constant in the other HRU(s). FIG. 3 includes a first plot 402 that illustrates power transitions of HRU1 and HRU2 during the IT Rack Replacement Test Sequence; a second plot 404 that spans the same time period and illustrates flow rate values sampled at HRU1, HRU2, and the IT rack; a third plot 406 that spans the same time period and illustrates pressure values sampled at HRU1, HRU2, and the IT rack; and a fourth plot 408 that spans the same time period and illustrates temperature variations observed at the IT rack. In FIG. 4, the temperature variations are shown for a single IT rack, which may be either the IT rack that has recently been replaced or an IT rack that has remained active and fully operational throughout the replacement of another IT rack on the same coolant loop. It is assumed that the cooling system configuration is such that all IT racks coupled to the same coolant loop observe temperature variations during the IT Rack Replacement Test Sequence that are substantially identical to those shown in the fourth plot 408. This additional data is excluded from FIG. 4 for brevity.

Although different implementations of the disclosed technology may utilize other power state configurations to generate data signals, the IT Rack Replacement Test Sequence generates a data signal by modulating the pump power at HRU1 while keeping the pump power constant for HRU2. This high/low pump power signal of HRU1 translates to a high/low response pattern detectable within pressure and flow rate telemetry streams sampled at different devices coupled to the coolant loop. Per this high/low power modulation, the modulating HRU (HRU1) is essentially acting as a transmitter that transmits a data signal along the coolant loop. The other device(s) on the coolant loop are acting as receivers that detect the data signal in their respective sensor telemetry. It is possible to verify that a data center technician has coupled the newly replaced IT rack to the correct ports on the existing cooling loop by verifying that a high/low signal received at the IT rack matches an expected response pattern corresponding to the signal transmitted by the modulating the HRU power. This expected response pattern is predetermined and stored in association with a logical identifier for the IT rack or its corresponding sensor package.

When generating the high/low power signals, it is critical to toggle the cooling system between power state configurations that are known to impart predictable changes on flow state characteristics—e.g., changes that are described by a linear response function. As discussed with respect to FIG. 3, some power state transitions may not cause predictable (linear) changes in the observed flow characteristics. Therefore, a first step in devising the IT Rack Replacement Test Sequence entails experimentally identifying a selection of power state configurations that impart changes in flow characteristics predictable by the linear response function.

Unlike the cooling system initiation operations described with respect to FIG. 2 (where the IT rack is not powered), the IT Rack Replacement Test Sequence may be performed while one or more IT racks on the coolant loop remain fully operational (generating heat). A major challenge in devising the IT Rack Replacement Test Sequence is, therefore, ensuring that transmission of the signal (the high/low pump modulation) does not alter the temperature of the coolant that is being delivered to any of the IT racks on the coolant loop. This entails identifying two cooling system power configurations, each specifying a power level for HRU1 and a power level for HRU 2, that the cooling system can toggle between without altering the temperature of coolant delivered to any of the IT racks in excess of a predefined magnitude, such as 1.5 degree or other range that is deemed “safe” for hardware that is being cooled. The data described above with respect to FIG. 3 is usable to identify pairs of suitable power state configurations (e.g., by first identifying a subset of power configurations that result in predictable flow characteristics and then identifying, from this subset, pairs of power state configurations that alter IT rack temperature by less than a defined threshold relative to a target temperature setpoint).

Once a suitable pair of power state configurations is identified per the above-described operations, a signal can be transmitted by toggling between the two power configurations—e.g., by keeping one HRU at a baseline power level while modulating the power of the other between the baseline level and a higher power level. Using the general technique described above, it is possible to construct various different signals to be transmitted through a liquid wire that circulates coolant in a liquid cooling system. For example, one or more different pairs of the above-described high/low power state configurations can be used, and different signals may be transmitted by holding the high and low states for different periods of time—creating detectable pulses of varying lengths.

The IT Rack Replacement Test Sequence illustrated by the power state transitions shown in the first plot 402 toggles HRU1 between a baseline power level representing a nominal operating power state and a higher power level. When HRU1 and HRU2 are both operating at the baseline power level, HRU1 and HRU2 are operating at 50% of the max power level and providing equal flow rate contribution to deliver the IT rack coolant of a target temperature. HRU1 is then modulated between the baseline power level and a higher power level every 10 seconds for two or more high/low repetitions, as shown. The higher power is, in the illustrated implementations, selected to be a power level that is 60% of max, which results in a detectable change in flow rate characteristics but a minimal increase in flow through the IT rack such that the temperature coolant delivered to the IT rack does not deviate by more than a predefined magnitude, such as 1.5 degrees.

An optimal length of time for each high/low modulation depends upon the sampling rate of the flow characteristics—ideally, multiple data points are sampled at each high/low modulation so as to yield a more easily detectable signal that matches the response patterns predicted by the linear response function for the corresponding power states.

When the power level of HRU1 is modulated to the higher power level (60%), the flow rate increases through HRU1 and decreases through HRU2, but the total flowrate through the IT rack remains equal to the sum of flowrates through HRU1 and HRU2. Likewise, pressure increases of different but predictable magnitudes are observed in HRU1, HRU2, and the IT rack. Because the power pump modulation is transitioning the system between power states known to impart linear (predictable) changes in the flow characteristics, the telemetry sensor response patterns 400 are replicated identically in repeated instances of the IT Rack Replacement Test Sequence executed in different loops with the same configuration of HRUs and IT racks.

The IT Rack Replacement Test Sequence can, in different implementations, be initiated in different ways. In one implementation, the IT rack replacement sequence is driven by an external processing system that transmits separate command(s) to cause each power level transition of HRU1. In another implementation, the IT Rack Replacement Test Sequence is stored in the firmware of each HRU and can be initiated in various ways, such as by transmitting a single command from an external processing system or by programming the HRU to execute the IT Rack Replacement Test Sequence in response to other trigger(s).

In one implementation, the IT rack that captures and transmits the sensor telemetry response patterns 400 to an external processing system that confirms the accuracy of a physical configuration between the first HRU and the first device by verifying that the sensor telemetry response patterns 400 match expected (stored) response patterns for the IT Rack Replacement Sequence. For example, this verification may entail confirming that flow rate through the IT rack modulates from a lower flow rate to a higher flow rate at intervals corresponding to predefined timing (matching the high/lower pump power levels of HRU1), confirming that a flow through the first IT rack matches a sum of flow rates measured across HRU1 and HRU2 at all times, and also confirming that pressure values measured on all three devices match a pattern of stored pressure values associated with the IT Rack Replacement Sequence.

In response to determining that the sensor telemetry response patterns 400 match the stored, expected response patterns for the IT Rack Replacement Sequence,
the external processing system records data indicating successful completion of the IT Rack Replacement Sequence, and the cooling system is permitted to continue with nominal operations. Alternatively, in response to determining that the sensor telemetry response patterns 400 do not match the stored, expected response patterns for the IT Rack Replacement Sequence, the external processing system generates a notification that flags a potential physical configuration error between the IT rack and HRU1 or HRU2. This notification is, for example, presented on the display of a device used by a data center technician.

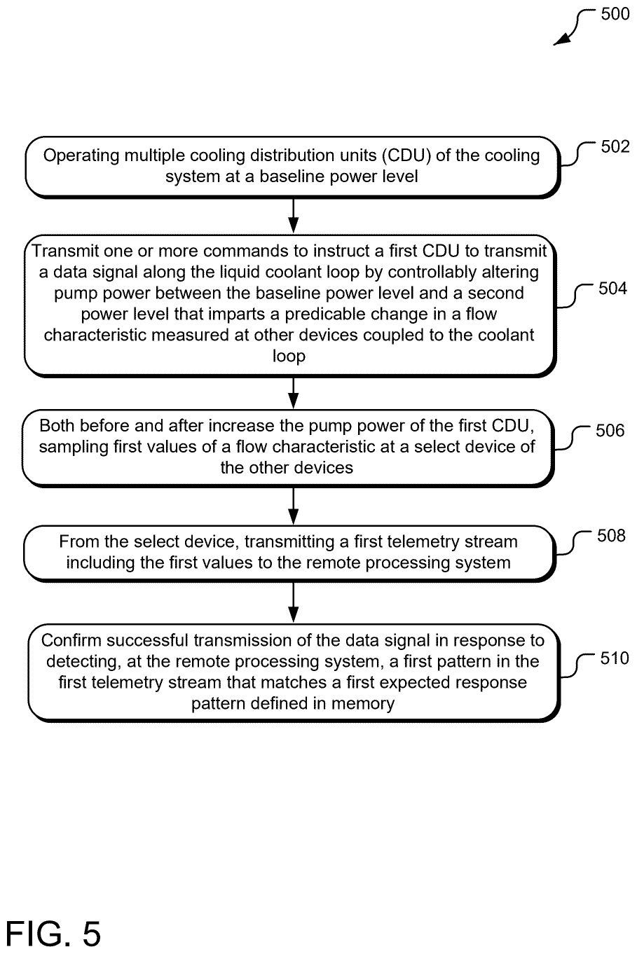

FIG. 5 illustrates example operations 500 for transmitting data between devices that lack direct electrical connectivity and that are coupled to a liquid coolant loop of a cooling system. The cooling system includes multiple HRUs, including at least a first HRU and a second HRU, that provides output flows to a manifold that combines the output flows into a single input flow received at an information technology (IT) rack.

A first operation 502 provides for operating the multiple HRUs at a baseline power level for a period of time. Following this period of time, a data transmission operation 504 transmits one or more commands to instruct the first HRU to transmit a data signal along the liquid coolant loop by controllably increasing pump power between the baseline power level and a second power level that imparts a predicable change in a flow characteristic measured at a subset of the devices. According to one implementation, the data transmission operation is performed by a processing system external to the liquid coolant loop, such as a rack controller at a data center.

A sampling operation 506 samples first values of a flow characteristic (or multiple different flow characteristics) at regular intervals both before and after the increase in pump power to the first HRU. The sampling operation 506 is performed at a select device of the devices coupled to the liquid coolant loop. A transmission operation 508 provides for transmitting a first telemetry stream that includes the first values sampled during the sampling operation 506. In one implementation, the transmission operation 508 transmits the first telemetry stream to the same processing system that performs the data transmission operation 504.

A signal verification operation 510 confirms the successful transmission of the data signal in response to detecting a first pattern in the first telemetry stream that matches a first expected response pattern defined in memory. For example, the first pattern defines expected changes in pressure at an IT Rack, the first HRU, and/or the second HRU that are associated with transitioning the first HRU from the baseline power level to the second power level. Alternatively or additionally, the first pattern defines expected relationships between flow rates measured at the IT rack and flow rates measured at the first HRU and the second HRU before and after the power level transition of the first HRU. For example, the signal verification operation 510 entails confirming that a flow rate measured at IT rack that equals a sum of flow rates measured at the HRUs both before the power state transition and after the power state transition. This signal verification operation 510 is, in one implementation, performed by the same processing system that performs the data transmission operation 504 and the transmission operation 508.

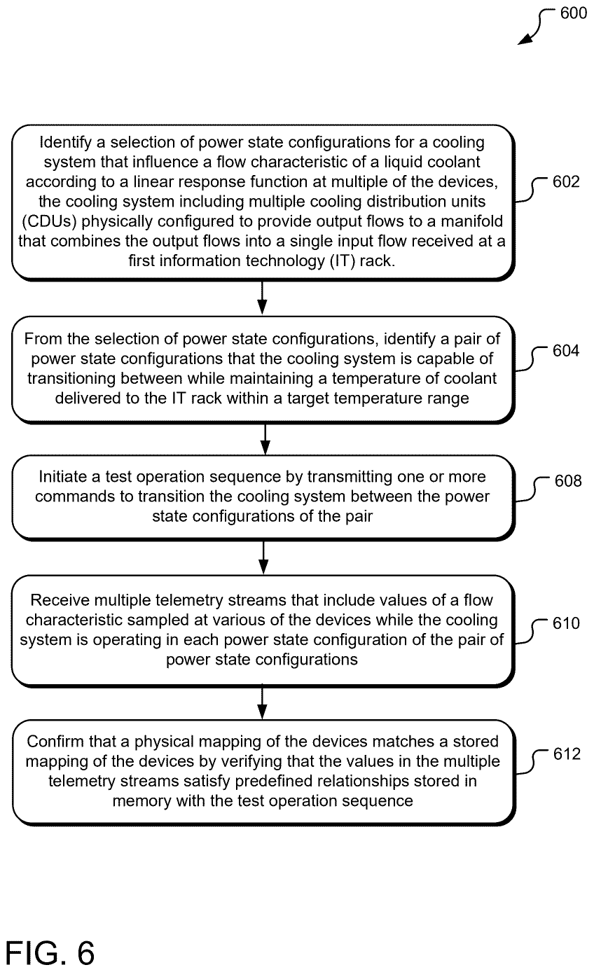

FIG. 6 illustrates example operations 600 for determining whether a physical mapping of devices in a cooling system matches an expected (stored) mapping of the devices. The cooling system includes multiple HRU, including at least a first HRU and a second HRU, physically configured to provide output flows to a manifold that combines the output flows into a flow that is received at one or multiple IT racks, with the IT racks being arranged either in series or in parallel with one another. The operations 600 do not require that the devices in the cooling system (HRUs and IT racks) be capable of communicating with one another across an electrical network. Further, the operations 600 can be performed while the cooling system is actively cooling one or more IT racks.

An identification operation 602 identifies a selection of power state configurations for the cooling system that impart predictable changes in a measured flow characteristic of a liquid coolant at multiple of the devices. This may result in a different selection of power state configurations due to the unique characteristics of the devices in the cooling system and the configuration of channels flowing coolant between the devices. For example, auto-closing check valves may not reliably close under identical pressure conditions, and this can cause flow characteristics to behave unpredictably when pressure conditions in a coolant loop are within a range where the check valve(s) could plausibly remain open or closed. Therefore, the identification operation 602 may, in some implementations, result in a selection of power state configurations that exclude power state configurations corresponding to channel pressures low enough for system check valve(s) to potentially remain open.

Likewise, when multiple HRUs operate in a parallel state configuration (e.g., as shown with respect to FIG. 1), flow characteristics may behave unpredictably when two or more HRUs operate at power levels that differ from one another by more than a threshold, such as 20%. Therefore, the identification operation 602 may, in some implementations, result in a selection of power state configurations that exclude power state configurations corresponding to HRU power levels that differ from one another more than a threshold amount.

An identification operation 604 identifies, from the selection of suitable power state configurations, a first power state configuration and a second power state configuration that the cooling system is capable of transitioning between while maintaining a temperature of coolant delivered to the IT rack within a target temperature range.

A test initiation operation 608 initiates a test operation sequence by transmitting one or more commands to transition the cooling system between a first power state configuration and a second power state configuration. The test initiation operation 608 may, for example, entail transmitting a single command to a HRU or multiple commands to the HRU that cause the HRU to alter its pump power level one or more times. In one implementation, the first power state configuration is a nominal power state configuration in which the HRUs are operated at an identical baseline power level. The second power state configuration provides for operating one of the HRUs at a second power level that is higher or lower than the baseline power level, while the other HRU(s) are operated at the baseline power level. In this implementation, the test operation sequence controllably alters the pump power of the first HRU between the baseline power level and the second power level while maintaining the pump power of the other HRUs at the baseline power level.

A telemetry receipt operation 610 receives multiple telemetry streams that include values of one or more flow characteristics sampled at various of the devices (e.g., the IT rack and HRUs) while the cooling system is operating in the first power state configuration and the second power state configuration.

A confirmation operation 612 confirms a physical mapping of the devices matches a stored expected mapping of the devices by verifying that the values in the multiple telemetry streams satisfy predefined relationships stored in memory with the test operation sequence.

In one implementation, the telemetry streams include flow rate measurements and verifying that the values satisfy the predefined relationships includes verifying that a flow rate measured at the IT rack matches a sum of flow rates measured at the multiple HRUs when the cooling system is in the first power state configuration and also when the cooling system is in the second power state configuration.

In the same or another implementation, the telemetry streams include pressure measurements and verifying that the values satisfy the predefined relationships additionally or alternatively includes verifying the that the transition between the first power state configuration and the second power state configuration correlates with an observed pressure change of predefined magnitude at each one of the devices.

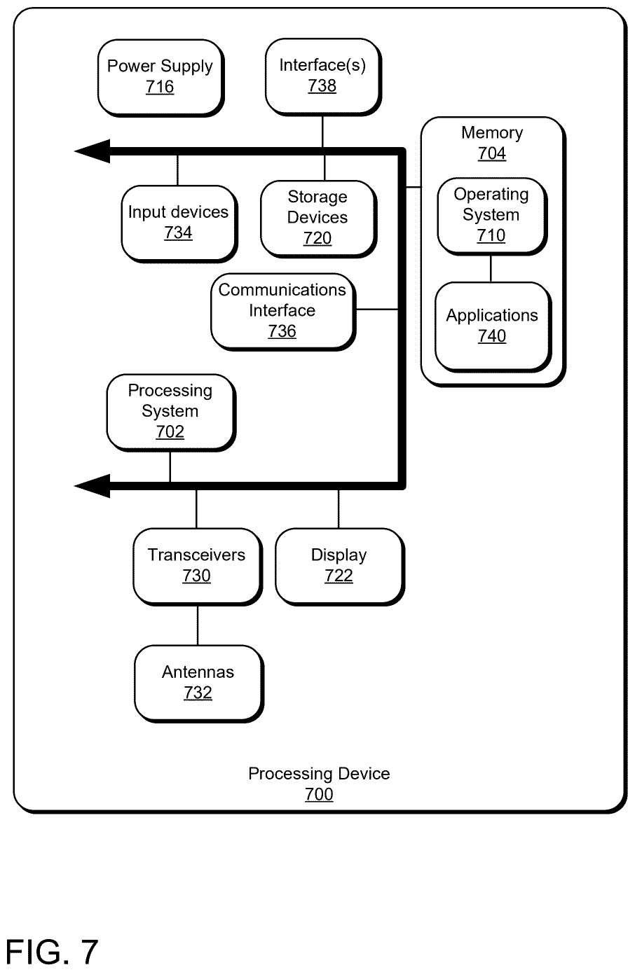

FIG. 7 illustrates an example computing device 700 for use in implementing the described technology. The computing device 700 may be part of a HRU control system or a rack controller in a data center that transmits power state transition commands to HRUs and receives sensor telemetry sampled at various devices coupled to different coolant loops. The computing device 700 includes one or more hardware processor(s) 702 and a memory 704. The memory 704 generally includes both volatile memory (e.g., RAM) and nonvolatile memory (e.g., flash memory), although one or the other type of memory may be omitted. An operating system 710 resides in the memory 704 and is executed by the processor(s) 702. In some implementations, the computing device 700 includes and/or is communicatively coupled to storage 720.

In the example computing device 700, one or more software modules, segments, and/or processors, such as applications 750 (e.g., applications for executing the herein-described test sequences) are loaded into the operating system 710 on the memory 704 and/or the storage 720 and executed by the processor(s) 702. The storage 720 may store commands or firmware sequences executable to transmit data signals by modulating the power of pump(s) circulating coolant through a liquid coolant loop.

The computing device 700 may include one or more communication transceivers 730, which may be connected to one or more antenna(s) 732 to provide network connectivity (e.g., mobile phone network, Wi-Fi®, Bluetooth®) to one or more other servers, client devices, IoT devices, and other computing and communications devices. The computing device 700 may further include a communications interface 736 (such as a network adapter or an I/O port, which are types of communication devices) that is used to establish connections over a wide-area network (WAN) or local-area network (LAN). It should be appreciated that the network connections shown are exemplary and that other communications devices and means for establishing a communications link between the computing device 700 and other devices may be used.

The computing device 700 may include one or more input devices 734 such that a user may enter commands and information (e.g., a keyboard, trackpad, or mouse). These and other input devices may be coupled to the server by one or more interfaces 738, such as a serial port interface, parallel port, or universal serial bus (USB). The computing device 700 may further include a display 722, such as a touchscreen display.

The computing device 700 may include a variety of tangible processor-readable storage media and intangible processor-readable communication signals. Tangible processor-readable storage can be embodied by any available media that can be accessed by the computing device 700 and can include both volatile and nonvolatile storage media and removable and non-removable storage media. Tangible processor-readable storage media excludes intangible, transitory communications signals (such as signals per se) and includes volatile and nonvolatile, removable, and non-removable storage media implemented in any method, process, or technology for storage of information such as processor-readable instructions, data structures, program modules, or other data. Tangible processor-readable storage media includes but is not limited to RAM, ROM, EEPROM, flash memory or other memory technology, CDROM, digital versatile disks (DVD) or other optical disk storage, magnetic cassettes, magnetic tape, magnetic disk storage, or other magnetic storage devices, or any other tangible medium which can be used to store the desired information and which can be accessed by the computing device 700. In contrast to tangible processor-readable storage media, intangible processor-readable communication signals may embody processor-readable instructions, data structures, program modules, or other data resident in a modulated data signal, such as a carrier wave or other signal transport mechanism. The term “modulated data signal” means a signal that has one or more of its characteristics set or changed in such a manner as to encode information in the signal. By way of example, and not limitation, intangible communication signals include signals traveling through wired media such as a wired network or direct-wired connection, and wireless media such as acoustic, RF, infrared, and other wireless media.

In some aspects, the techniques described herein relate to a method of transmitting data between devices that lack direct electrical connectivity and that are coupled to a liquid coolant loop of a cooling system, the method including: operating multiple heat rejection units (HRUs) of the cooling system at a baseline power level, the multiple HRUs being physically configured to provide output flows to a manifold that combines the output flows into a single input flow received at a first information technology (IT) rack; identifying pair of power state configurations that the cooling system is capable of transitioning between while maintaining a temperature of coolant delivered to the IT rack within a target temperature range, the pair of power state configurations including a first power state configuration and a second power state configuration; from a processing system, transmitting one or more commands to instruct a first HRU of the multiple HRUs to transmit a data signal along the liquid coolant loop by controllably altering a power state of the cooling system between the first power state configuration and the second power state configuration; both before and after altering the power state of the cooling system, sampling first values of a flow characteristic at a select one of the devices and transmitting a first telemetry stream including the first values to the processing system; and confirming successful transmission of the data signal in response to detecting, at the processing system, a first pattern in the first telemetry stream that matches a first expected response pattern defined in memory.

In some aspects, the techniques described herein relate to a method, wherein controllably altering the power state configuration is performed during nominal operations of the cooling system while power is provided to the first IT rack, and wherein the multiple HRUs operate at a baseline power level in the first power configuration state.

In some aspects, the techniques described herein relate to a method, wherein operating the cooling system in the second power state configuration includes operating the first HRU at a second power level different from the baseline power level and operating one or more other HRUs at the baseline power level.

In some aspects, the techniques described herein relate to a method, wherein the second power level is selected to ensure that transitioning the first HRU between the baseline power level and the second power level imparts a predicable change in a flow characteristic at a subset of the devices and without altering temperature of the single input flow to the first IT rack in excess of a predefined magnitude.

In some aspects, the techniques described herein relate to a method, wherein the first telemetry stream is transmitted by the first IT rack and the first expected response pattern includes values of a flow rate measured at the first IT rack that toggle between a nominal flow rate and a higher flow rate, and wherein detecting the first pattern further includes: confirming the higher flow rate through the first IT rack matches a sum of flow rates measured across the multiple HRUs while the first HRU is operating at the second power level.

In some aspects, the techniques described herein relate to a method, further including: from the processing system, controllably modulating pump power of a second HRU of the multiple HRUs between the baseline power level and the second power level; while controllably altering the pump power of the second HRU, sampling second values of the flow characteristic at the first IT rack and transmitting a second telemetry stream including the second values to the processing system; in response to detecting, at the processing system, a second pattern in the second telemetry stream that matches second expected response pattern defined in memory, confirming that a physical coupling exists between the second HRU and the first IT rack; in response to failing to detect the second pattern in the second telemetry stream, generating a notification that flags a potential physical configuration error between the second HRU and the first IT rack.

In some aspects, the techniques described herein relate to a method, wherein the first telemetry stream includes flow rate values and pressure values sampled at the first IT rack and wherein detecting the first pattern includes determining that the flow rate values and pressure values match expected values defined by the first expected response pattern.

In some aspects, the techniques described herein relate to a method, wherein the first expected response pattern is defined association with a first position in a physical device configuration mapping and wherein the method further includes: in response to failing to detect the first expected response pattern in the first telemetry stream, generating a notification that flags a potential physical device configuration error.

In some aspects, the techniques described herein relate to a method, wherein the method further includes: selecting the second power level by operations that include: identifying a selection of power state configurations of the cooling system that yield a linear response in pressure and flow rate at each other one of the devices in the cooling system, wherein the selection of power state configurations includes at least a first power configuration that provides for operating the first HRU at the second power level and all other HRUs at the baseline power level.

In some aspects, the techniques described herein relate to a method, wherein the first values in the first telemetry stream are sampled by a sensor at the first IT rack and confirming successful transmission of the data signal includes recording data that confirms a physical coupling the first IT rack and the first HRU.

In some aspects, the techniques described herein relate to a liquid cooling system including: a first information technology (IT) rack; multiple heat rejection units (HRUs) coupled to a coolant loop and configured to provide output flows to a manifold that combine the output flows into a single input flow received at the first IT rack; a first firmware sequence stored in memory of the first IT rack and executable by a processing system of the IT rack to locally sample values of a flow characteristic at predefined intervals and transmit a first telemetry stream including the values; a second firmware sequence stored in a first HRU of the multiple HRUs, the second firmware sequence executable to transmit a data signal via a liquid coolant by a controllably modulating pump power of the first HRU between a baseline power level and a second power level impart a predictable change in the flow characteristic measured at the first IT rack, wherein a temperature of coolant delivered to the IT rack is maintained within a target temperature range while the pump power of the first HRU is modulated between he baseline power level and the second power level; and processor-executable instructions stored in memory and executable by a processing system to: transmit a command to the first HRU that initiates the second firmware sequence; receive a first portion of the first telemetry stream from the first IT rack corresponding to an execution time period of the second firmware sequence by the first HRU; and confirm accuracy of a physical configuration between the first IT rack and the first HRU by verifying that a first pattern in the first portion of the first telemetry stream matches a first expected response pattern defined in memory; and generate a notification that flags a potential physical device configuration error in response to determining that the first pattern in the first portion of the first telemetry stream does not match the first expected response pattern.

In some aspects, the techniques described herein relate to a liquid cooling system, wherein the processing system transmits the command during nominal operations of the liquid cooling system and while power is provided to the first IT rack, and wherein one or more other HRUs in the liquid cooling system operate at the baseline power level during the second firmware sequence and the baseline power level is selected to ensure the single input flow to the first IT rack is of a target temperature when all HRUs are operating at the baseline power level.

In some aspects, the techniques described herein relate to a liquid cooling system, wherein the second power level is selected to ensure that the predictable change in the flow characteristic at the first IT rack occurs without altering temperature of the single input flow to the first IT rack in excess of a predefined magnitude.

In some aspects, the techniques described herein relate to a liquid cooling system, wherein the first expected response pattern includes flow rate values that toggle between a lower flow rate and a higher flow rate, and wherein the processing system detects the first pattern in response to confirming the higher flow rate through the first IT rack matches a sum of flow rates measured at the multiple HRUs while the first HRU is operating at the second power level.

In some aspects, the techniques described herein relate to a liquid cooling system, wherein the baseline power level is a zero power level, and wherein the processing system detects the first pattern in response to confirming that the first telemetry stream includes values of a flow rate that toggle between a zero flow rate and a higher flow rate, the higher flow rate matching a flow rate sampled at the first HRU while the first HRU is operating at the second power level.

In some aspects, the techniques described herein relate to a liquid cooling system, wherein the second firmware sequence is also stored in a second HRU of the multiple HRUs and the processing system is further configured to: subsequent to detecting the first pattern in the first telemetry stream, transmit a command to the second HRU that instructs initiation of the second firmware sequence; receive a second portion of the first telemetry stream from the first IT rack corresponding to an execution time period of the second firmware sequence by the second HRU; in response to verifying that the second portion of the first telemetry stream includes a second pattern that matches the first expected response pattern, confirm that a physical configuration of the first IT rack and the second HRU matches an expected physical mapping.

In some aspects, the techniques described herein relate to a liquid cooling system, wherein the first telemetry stream includes flow rate values and pressure values sampled at the first IT rack and wherein verifying that the first pattern in the first portion of the first telemetry stream matches the first expected response pattern includes confirming that the flow rate values and the pressure values match expected values defined by the first expected response pattern.

In some aspects, the techniques described herein relate to a method of determining whether a physical mapping of devices in a liquid cooling system matches an expected mapping of the devices, the method including: experimentally identifying a selection of power state configurations for the liquid cooling system that impart predictable changes in a measured flow characteristic of a liquid coolant at multiple of the devices, the liquid cooling system including multiple heat rejection units (HRUs) physically configured to provide output flows to a manifold that combines the output flows into a single input flow received at a first information technology (IT) rack; from the selection of power state configurations, identifying identify a pair of power state configurations that the cooling system is capable of transitioning between while maintaining a temperature of coolant delivered to the IT rack within a target temperature range, the pair of power state configurations including a first power state configuration and a second power state configuration; initiating a test operation sequence by transmitting one or more commands to transition the cooling system from the first power state configuration to the second power state configuration; receiving multiple telemetry streams that include values of a flow characteristic sampled at various of the devices while the cooling system is operating in the first power state configuration and the second power state configuration; and confirming that the physical mapping of the devices matches the expected mapping of the devices by verifying that the values in the multiple telemetry streams satisfy predefined relationships stored in memory with the test operation sequence.

In some aspects, the techniques described herein relate to a method, wherein the values include flow rate measurements and verifying that the values satisfy the predefined relationships includes verifying that a flow rate measured at the IT rack matches a sum of flow rates measured at the multiple HRUs when the cooling system is in the first power state configuration and also when the cooling system is in the second power state configuration.

In some aspects, the techniques described herein relate to a method, wherein the values include pressure measurements and verifying that the values satisfy the predefined relationships further includes verifying the transition between the first power state configuration and the second power state configuration correlates with a pressure change of predefined magnitude at each one of the devices.

The logical operations described herein are implemented as logical steps in one or more computer systems. The logical operations may be implemented (1) as a sequence of processor-implemented steps executing in one or more computer systems and (2) as interconnected machine or circuit modules within one or more computer systems. The implementation is a matter of choice, dependent on the performance requirements of the computer system being utilized. Accordingly, the logical operations making up the implementations described herein are referred to variously as operations, steps, objects, or modules. Furthermore, it should be understood that logical operations may be performed in any order, unless explicitly claimed otherwise or a specific order is inherently necessitated by the claim language. The above specification, examples, and data, together with the attached appendices, provide a complete description of the structure and use of example implementations.

What is claimed is:

1. A method of transmitting data between devices that lack direct electrical connectivity and that are coupled to a liquid coolant loop of a cooling system, the method comprising:
operating multiple heat rejection units (HRUs) of the cooling system at a baseline power level, the multiple HRUs being physically configured to provide output flows to a manifold that combines the output flows into a single input flow received at a first information technology (IT) rack;
identifying pair of power state configurations that the cooling system is capable of transitioning between while maintaining a temperature of coolant delivered to the IT rack within a target temperature range, the pair of power state configurations including a first power state configuration and a second power state configuration;
from a processing system, transmitting one or more commands to instruct a first HRU of the multiple HRUs to transmit a data signal along the liquid coolant loop by controllably altering a power state of the cooling system between the first power state configuration and the second power state configuration;
both before and after altering the power state of the cooling system, sampling first values of a flow characteristic at a select one of the devices and transmitting a first telemetry stream including the first values to the processing system; and
confirming successful transmission of the data signal in response to detecting, at the processing system, a first pattern in the first telemetry stream that matches a first expected response pattern defined in memory.

2. The method of claim 1, wherein controllably altering the power state configuration is performed during nominal operations of the cooling system while power is provided to the first IT rack, and wherein the multiple HRUs operate at a baseline power level in the first power configuration state.

3. The method of claim 2, wherein operating the cooling system in the second power state configuration includes operating the first HRU at a second power level different from the baseline power level and operating one or more other HRUs at the baseline power level.

4. The method of claim 3, wherein the second power level is selected to ensure that transitioning the first HRU between the baseline power level and the second power level imparts a predicable change in a flow characteristic at a subset of the devices and without altering temperature of the single input flow to the first IT rack in excess of a predefined magnitude.

5. The method of claim 2, wherein the first telemetry stream is transmitted by the first IT rack and the first expected response pattern includes values of a flow rate measured at the first IT rack that toggle between a nominal flow rate and a higher flow rate, and wherein detecting the first pattern further comprises:
confirming the higher flow rate through the first IT rack matches a sum of flow rates measured across the multiple HRUs while the first HRU is operating at the second power level.

6. The method of claim 4, further comprising:
from the processing system, controllably modulating pump power of a second HRU of the multiple HRUs between the baseline power level and the second power level;
while controllably altering the pump power of the second HRU, sampling second values of the flow characteristic at the first IT rack and transmitting a second telemetry stream including the second values to the processing system;
in response to detecting, at the processing system, a second pattern in the second telemetry stream that matches second expected response pattern defined in memory, confirming that a physical coupling exists between the second HRU and the first IT rack;
in response to failing to detect the second pattern in the second telemetry stream, generating a notification that flags a potential physical configuration error between the second HRU and the first IT rack.

7. The method of claim 1, wherein the first telemetry stream includes flow rate values and pressure values sampled at the first IT rack and wherein detecting the first pattern includes determining that the flow rate values and pressure values match expected values defined by the first expected response pattern.

8. The method of claim 1, wherein the first expected response pattern is defined association with a first position in a physical device configuration mapping and wherein the method further comprises:
in response to failing to detect the first expected response pattern in the first telemetry stream, generating a notification that flags a potential physical device configuration error.

9. The method of claim 3, wherein the method further comprises:
selecting the second power level by operations that include:
identifying a selection of power state configurations of the cooling system that yield a linear response in pressure and flow rate at each other one of the devices in the cooling system, wherein the selection of power state configurations includes at least a first power configuration that provides for operating the first HRU at the second power level and all other HRUs at the baseline power level.

10. The method of claim 1, wherein the first values in the first telemetry stream are sampled by a sensor at the first IT rack and confirming successful transmission of the data signal includes recording data that confirms a physical coupling the first IT rack and the first HRU.

11. A liquid cooling system comprising:
a first information technology (IT) rack;
multiple heat rejection units (HRU) coupled to a coolant loop and configured to provide output flows to a manifold that combine the output flows into a single input flow received at the first IT rack;
a first firmware sequence stored in memory of the first IT rack and executable by a processing system of the IT rack to locally sample values of a flow characteristic at predefined intervals and transmit a first telemetry stream including the values;
a second firmware sequence stored in a first HRU of the multiple HRUs, the second firmware sequence executable to transmit a data signal via a liquid coolant by a controllably modulating pump power of the first HRU between a baseline power level and a second power level impart a predictable change in the flow characteristic measured at the first IT rack, wherein a temperature of coolant delivered to the IT rack is maintained within a target temperature range while the pump power of the first HRU is modulated between he baseline power level and the second power level; and
processor-executable instructions stored in memory and executable by a processing system to:
transmit a command to the first HRU that initiates the second firmware sequence;
receive a first portion of the first telemetry stream from the first IT rack corresponding to an execution time period of the second firmware sequence by the first HRU; and
confirm accuracy of a physical configuration between the first IT rack and the first HRU by verifying that a first pattern in the first portion of the first telemetry stream matches a first expected response pattern defined in memory; and
generate a notification that flags a potential physical device configuration error in response to determining that the first pattern in the first portion of the first telemetry stream does not match the first expected response pattern.

12. The liquid cooling system of claim 11,
wherein the processing system transmits the command during nominal operations of the liquid cooling system and while power is provided to the first IT rack, and
wherein one or more other HRUs in the liquid cooling system operate at the baseline power level during the second firmware sequence and the baseline power level is selected to ensure the single input flow to the first IT rack is of a target temperature when all HRUs are operating at the baseline power level.

13. The liquid cooling system of claim 12, wherein the second power level is selected to ensure that the predictable change in the flow characteristic at the first IT rack occurs without altering temperature of the single input flow to the first IT rack in excess of a predefined magnitude.

14. The liquid cooling system of claim 12, wherein the first expected response pattern includes flow rate values that toggle between a lower flow rate and a higher flow rate, and wherein the processing system detects the first pattern in response to confirming the higher flow rate through the first IT rack matches a sum of flow rates measured at the multiple HRUs while the first HRU is operating at the second power level.

15. The liquid cooling system of claim 12, wherein the baseline power level is a zero power level, and wherein the processing system detects the first pattern in response to confirming that the first telemetry stream includes values of a flow rate that toggle between a zero flow rate and a higher flow rate, the higher flow rate matching a flow rate sampled at the first HRU while the first HRU is operating at the second power level.

16. The liquid cooling system of claim 11, wherein the second firmware sequence is also stored in a second HRU of the multiple HRUs and the processing system is further configured to:
subsequent to detecting the first pattern in the first telemetry stream, transmit a command to the second HRU that instructs initiation of the second firmware sequence;
receive a second portion of the first telemetry stream from the first IT rack corresponding to an execution time period of the second firmware sequence by the second HRU;
in response to verifying that the second portion of the first telemetry stream includes a second pattern that matches the first expected response pattern, confirm that a physical configuration of the first IT rack and the second HRU matches an expected physical mapping.

17. The liquid cooling system of claim 11, wherein the first telemetry stream includes flow rate values and pressure values sampled at the first IT rack and wherein verifying that the first pattern in the first portion of the first telemetry stream matches the first expected response pattern includes confirming that the flow rate values and the pressure values match expected values defined by the first expected response pattern.

18. A method of determining whether a physical mapping of devices in a liquid cooling system matches an expected mapping of the devices, the method comprising:
experimentally identifying a selection of power state configurations for the liquid cooling system that impart predictable changes in a measured flow characteristic of a liquid coolant at multiple of the devices, the liquid cooling system including multiple heat rejection units (HRUs) physically configured to provide output flows to a manifold that combines the output flows into a single input flow received at a first information technology (IT) rack;
from the selection of power state configurations, identifying identify a pair of power state configurations that the cooling system is capable of transitioning between while maintaining a temperature of coolant delivered to the IT rack within a target temperature range, the pair of power state configurations including a first power state configuration and a second power state configuration;
initiating a test operation sequence by transmitting one or more commands to transition the cooling system from the first power state configuration to the second power state configuration;
receiving multiple telemetry streams that include values of a flow characteristic sampled at various of the devices while the cooling system is operating in the first power state configuration and the second power state configuration; and
confirming that the physical mapping of the devices matches the expected mapping of the devices by verifying that the values in the multiple telemetry streams satisfy predefined relationships stored in memory with the test operation sequence.

19. The method of claim 18, wherein the values include flow rate measurements and verifying that the values satisfy the predefined relationships includes verifying that a flow rate measured at the IT rack matches a sum of flow rates measured at the multiple HRUs when the cooling system is in the first power state configuration and also when the cooling system is in the second power state configuration.

20. The method of claim 19, wherein the values include pressure measurements and verifying that the values satisfy the predefined relationships further includes verifying the transition between the first power state configuration and the second power state configuration correlates with a pressure change of predefined magnitude at each one of the devices.
